(19) United States
(12) Patent Application Publication
(10) Pub. No.: US 2026/0190614 A1
(43) Pub. Date: Jul. 2, 2026

(54) DISPLAY DEVICE

(71) Applicant: LG Display Co., Ltd., Seoul (KR)

(72) Inventors: EunYoung PARK, Paju-si (KR); YuRi KOH, Paju-si (KR); Kimin LIM, Paju-si (KR)

(73) Assignee: LG Display Co., Ltd., Seoul (KR)

(21) Appl. No.: 19/220,455

(22) Filed: May 28, 2025

(30) Foreign Application Priority Data
Dec. 31, 2024 (KR) 10-2024-0201729

(51) Int. Cl. H10K 50/18; H10K 59/35; H10K 101/30; H10K 102/00

(52) U.S. Cl. CPC H10K 50/181; H10K 59/35; H10K 2101/30; H10K 2102/351

(57) ABSTRACT

A display device according to one or more examples may include a plurality of light emitting elements disposed on a substrate. At least one of the plurality of light emitting elements may include a first electrode disposed on the substrate, an electron blocking layer disposed on the first electrode, a light emitting layer disposed on the electron blocking layer and including a host and a dopant, and a second electrode disposed on the light emitting layer. A highest occupied molecular orbital (HOMO) energy level of the electron blocking layer may be lower than an HOMO energy level of the host. Therefore, there may be provided a display device capable of increasing the efficiency and lifespan and reducing power consumption.

### CROSS-REFERENCE TO RELATED APPLICATION

This application claims the benefit of and priority to Korean Patent Application No. 10-2024-0201729, filed on Dec. 31, 2024, the entire contents of which are incorporated herein by reference for all purposes as if fully set forth herein.

### BACKGROUND

### 1. Technical Field

Embodiments of the disclosure relate to a display device.

### 2. Description of Related Art

With the development of technology, the display device may provide a capture function and various detection functions in addition to an image display function. To this end, the display device may have an optical electronic device (also referred to as a light receiving device or sensor), such as a camera and a detection sensor.

Since the optical electronic device receives light from the front of the display device, it should be installed where light reception is easy. Accordingly, conventionally, the camera (camera lens) and the detection sensor had to be installed to be exposed on the front surface of the display device. Thus, the bezel of the display panel is widened or a notch or physical hole is formed in the display area of the display panel, and a camera or a detection sensor is installed there.

Therefore, as the display device is equipped with optical electronic devices such as cameras, detection sensors, etc. that perform a specified function by receiving light from the front, the front of the display device may have a large bezel or the front design of the display device may be restricted.

The description of related art should not be considered prior art merely because it is mentioned in or associated with this section. The description of related art includes information that describes one or more aspects of the subject technology, and the description in this section does not limit the scope of the invention.

### SUMMARY

Embodiments of the disclosure may provide a display device having a light transmission structure in which an optical electronic device may normally receive light (e.g., visible light, infrared light, or ultraviolet light) without exposing the optical electronic device through the front surface of the display device.

Embodiments of the disclosure may provide a display device capable of implementing a full screen display by positioning various optical electronic devices to overlap under the display area of the display panel to allow the entire area of the display panel to be used as the display area.

Embodiments of the disclosure may provide a display device capable of quickly driving light emitting elements by adjusting the materials included in the light emitting layer in the normal area and the optical area.

Embodiments of the disclosure may provide a display device capable of quickly emitting holes by adjusting the materials included in the light emitting layer in the normal area and the optical area.

Embodiments of the disclosure may provide a display device capable of enhancing the surface characteristics of the display device by including different dopants in the light emitting layer in the optical area and the normal area.

Embodiments of the disclosure may provide a display device capable of increasing the reliability of the light emitting element by reducing the luminance deterioration and lifespan reduction in the display area.

Aspects of the disclosure are not limited to those set forth herein, and other unmentioned aspects would be apparent to one of ordinary skill in the art from the following description.

Embodiments of the disclosure may provide a display device comprising a plurality of light emitting elements disposed on a substrate, wherein at least one of the plurality of light emitting elements includes a first electrode disposed on the substrate, an electron blocking layer disposed on the first electrode, a light emitting layer disposed on the electron blocking layer and including a host and a dopant, and a second electrode disposed on the light emitting layer, and wherein a highest occupied molecular orbital (HOMO) energy level of the electron blocking layer is lower than an HOMO energy level of the host.

According to embodiments of the disclosure, there may be provided a display device having a light transmission structure in which an optical electronic device may normally receive light (e.g., visible light, infrared light, or ultraviolet light) without exposing the optical electronic device through the front surface of the display device.

According to embodiments of the disclosure, there may be provided a display device capable of implementing a full screen display by positioning various optical electronic devices to overlap under the display area of the display panel to allow the entire area of the display panel to be used as the display area.

According to embodiments of the disclosure, there may be provided a display device capable of quickly driving light emitting elements by adjusting the materials included in the light emitting layer in the normal area and the optical area.

According to embodiments of the disclosure, there may be provided a display device capable of quickly emitting holes by adjusting the materials included in the light emitting layer in the normal area and the optical area.

According to embodiments of the disclosure, there may be provided a display device capable of enhancing the surface characteristics of the display device by including different dopants in the light emitting layer in the optical area and the normal area.

According to embodiments of the disclosure, there may be provided a display device capable of increasing the reliability of the light emitting element by reducing the luminance deterioration and lifespan reduction in the display area.

According to embodiments of the disclosure, there may be provided a display device capable of increasing the efficiency and lifespan of the display device and reducing power consumption by decreasing the luminance deterioration and lifespan reduction in the display area.

The effects of the disclosure are not limited to the foregoing aspects, and other effects will be apparent to one of ordinary skill in the art from the following detailed description.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a view illustrating an example configuration of a display device according to embodiments of the disclosure;

FIG. 2 is a view illustrating an example system configuration of a display device according to embodiments of the disclosure;

FIG. 3 is a view illustrating an example configuration of a display device according to embodiments of the disclosure;

FIG. 4 is a view illustrating an example arrangement of subpixels in three areas included in a display area of a display device according to embodiments of the disclosure;

FIG. 5 is an example cross-sectional view illustrating an optical area of a display panel according to embodiments of the disclosure;

FIGS. 6 and 7 are example cross-sectional views illustrating light emitting elements disposed in a normal area and an optical area, respectively, of a display panel according to embodiments of the disclosure;

FIG. 8 is an example view illustrating an energy band diagram for a light emitting element disposed in an optical area of a display panel according to embodiments of the disclosure; and

FIGS. 9 to 11 are example graphs illustrating characteristics of a light emitting element in an optical area of a display panel according to embodiments of the disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting”, “make up of”, and “formed of” used herein are generally intended to allow other components to be added unless the terms are used with the term “only”. As used herein, singular forms are intended to include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after”, “subsequent to”, “next”, “before”, and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

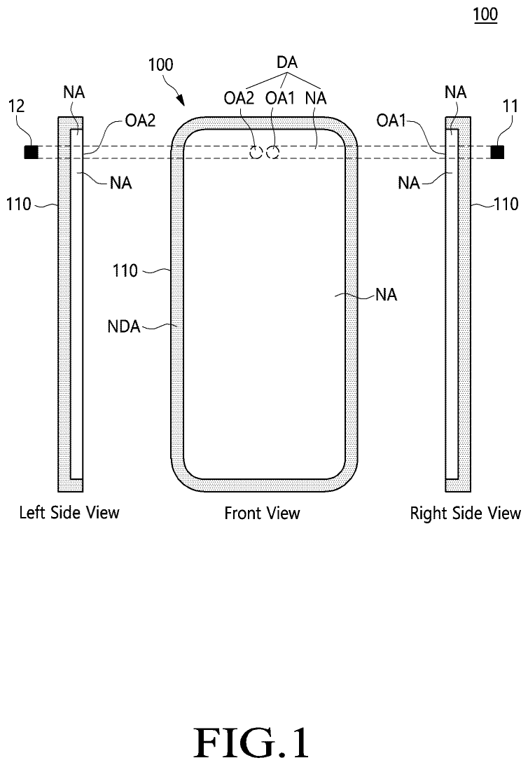

FIG. 1 is a view illustrating an example configuration of a display device 100 according to embodiments of the disclosure.

Referring to FIG. 1, the display device 100 according to embodiments of the disclosure may include a display panel 110 for displaying an image and one or more optical electronic devices 11 and 12.

The display panel 110 may include a display area DA in which images (videos) may displayed and a non-display area NDA in which no image is displayed.

A plurality of subpixels may be disposed in the display area DA, and various signal lines for driving the plurality of subpixels may be disposed in the display area AA.

The non-display area NDA may be an area outside the display area DA. In the non-display area NDA, various signal lines may be disposed, and various driving circuits may be connected thereto. The non-display area NDA may be bent to be invisible from the front or may be covered by a case (not shown). The non-display area NDA may also be referred to as a bezel or a bezel area.

Referring to FIG. 1, in the display device 100 according to embodiments of the disclosure, one or more optical electronic devices 11 and 12 may be electronic components that are provided and installed separately from the display panel 110 and positioned under the display panel 110 (side opposite to the viewing surface).

Light enters the front surface (viewing surface) of the display panel 110 and passes through the display panel 110 to one or more optical electronic devices 11 and 12 positioned under the display panel 110 (opposite to the viewing surface). For example, the light passing through the display panel 110 may include visible light, infrared light, or ultraviolet light.

The one or more optical electronic devices 11 and 12 may be devices that receive the light transmitted through the display panel 110 and perform a predetermined function according to the received light. For example, the one or more optical electronic devices 11 and 12 may include one or more of a capture device, such as a camera (image sensor), and a detection sensor, such as a proximity sensor and an illuminance sensor. For example, the detection sensor may be an infrared sensor.

Referring to FIG. 1, the display area DA in the display panel 110 according to embodiments of the disclosure may include the normal area NA and one or more optical areas OA1 and OA2. The one or more optical areas OA1 and OA2 may be areas overlapping the one or more optical electronic devices 11 and 12.

Meanwhile, although FIG. 1 illustrates a structure including two optical areas OA1 and OA2, it may include one first optical area OA1 and a normal area NA. At least a portion of the first optical area OA1 may overlap the first optical electronic device 11.

The one or more optical areas OA1 and OA2 should have both an image display structure and a light transmission structure. In other words, since the one or more optical areas OA1 and OA2 are partial areas of the display area DA, emission areas of subpixels for displaying images should be disposed in the one or more optical areas OA1 and OA2. A light transmission structure for transmitting light to the one or more optical and electronic devices 11 and 12 should be formed in one or more optical areas OA1 and OA2.

Hereinafter, for convenience of description, it is assumed that the first optical electronic device 11 is a camera and the second electronic device 12 is an infrared (IR)-based detection sensor. The camera may be a camera lens or an image sensor.

The normal area NA and one or more optical areas OA1 and OA2 included in the display area DA may be areas capable of displaying an image. The normal area NA may be an area where a light transmission structure is not required to be formed, and one or more optical areas OA1 and OA2 may be areas in which a light transmission structure is to be formed.

Accordingly, the one or more optical areas OA1 and OA2 should have a transmittance higher than or equal to a certain level, and the normal area NA may have no light transmittance or a lower transmittance less than the certain level.

For example, one or more optical areas OA1 and OA2 and the normal area NA may have different resolutions, subpixel placement structures, numbers of subpixels per unit area, electrode structures, line structures, electrode placement structures, or line placement structures.

For example, the number of subpixels per unit area in one or more optical areas OA1 and OA2 may be smaller than the number of subpixels per unit area in the normal area NA. In other words, the resolution of one or more optical areas OA1 and OA2 may be lower than the resolution of the normal area NA. Here, the number of subpixels per unit area may be meant to be equivalent to resolution, or pixel density, or pixel integration degree. For example, the unit for the number of subpixels per unit area may be pixels per inch (PPI), which means the number of pixels in one inch.

The first optical area OA1 may have various shapes, such as a circle, an ellipse, a quadrangle, a hexagon, or an octagon. The second optical area OA2 may have various shapes, such as a circle, an ellipse, a square, a hexagon, or an octagon. The first optical area OA1 and the second optical area OA2 may have the same shape or different shapes. Hereinafter, for convenience of description, each of the first optical area OA1 and the second optical area OA2 is exemplified as having a circular shape.

In the display device 100 according to embodiments of the disclosure, if the first optical electronic device 11 that is not exposed to the outside and is hidden in a lower portion of the display panel 100 is a camera, the display device 100 according to embodiments of the disclosure may be referred to as a display to which under display camera (UDC) technology has been applied.

Accordingly, the display device 100 according to embodiments of the disclosure does not require a notch or camera hole for camera exposure to be formed in the display panel 110, thereby preventing a reduction in the display area DA. Thus, as there is no need to form a notch or camera hole for exposure of the camera in the display panel 110, the size of the bezel area may be reduced, and design restrictions may be freed, thereby increasing the degree of freedom in design.

In the display device 100 according to embodiments of the disclosure, if the second optical electronic device 12 that is not exposed to the outside and is hidden in a lower portion of the display panel 100 is an infrared (IR) sensor, the display device 100 according to embodiments of the disclosure may be referred to as a display to which under display infrared (UDIR) technology has been applied.

In the display device 100 according to embodiments of the disclosure, although one or more optical electronic devices 11 and 12 are positioned to be hidden behind the display panel 110, one or more optical electronic devices 11 and 12 should be able to normally perform predetermined functions by normally receiving light.

Further, in the display device 100 according to embodiments of the disclosure, although one or more optical electronic devices 11 and 12 are positioned to be hidden behind the display panel 110 and are positioned to overlap the display area DA, the one or more optical areas OA1 and OA2 overlapping the one or more optical electronic devices 11 and 12 in the display area DA should be capable of normal image display.

Since the above-mentioned first optical area OA1 is designed as a transmittable area, the image display characteristics in the first optical area OA1 may differ from the image display characteristics in the normal area NA.

Further, in designing the first optical area OA1 to enhance the image display characteristics, the transmittance of the first optical area OA1 may be degraded.

Accordingly, embodiments of the disclosure propose a structure of the first optical area OA1 capable of enhancing transmittance in the first optical area OA1 without causing an image quality deviation between the first optical area OA1 and the normal area NA.

Further, embodiments of the disclosure propose a structure of the second optical area OA2 capable of enhancing transmittance in the second optical area OA2 and image quality in the second optical area OA2 for the second optical area OA2, as well as for the first optical area OA1.

Further, in the display device 100 according to embodiments of the disclosure, the first optical area OA1 and the second optical area OA2 are similar in that they are light transmittable areas, but differ in use cases. Therefore, in the display device 100 according to embodiments of the disclosure, the structure of the first optical area OA1 and the structure of the second optical area OA2 may be designed to differ from each other.

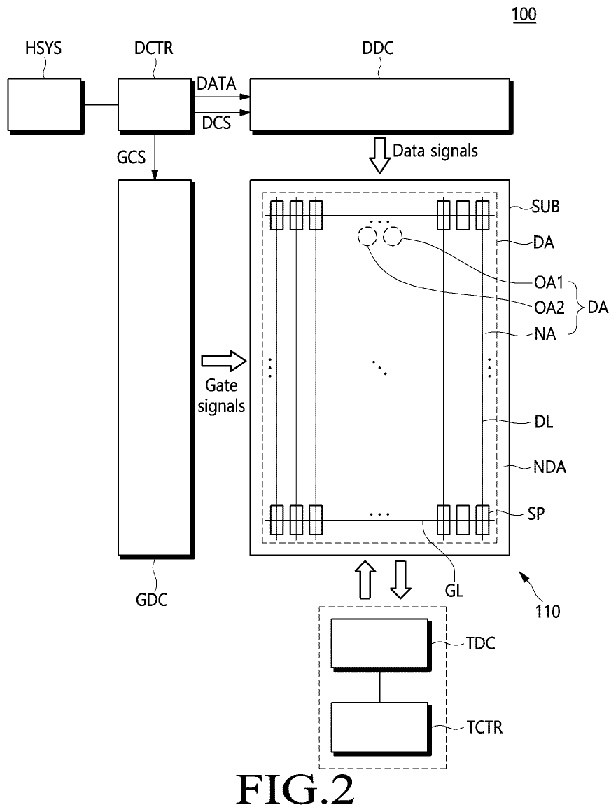

FIG. 2 is a view illustrating an example system configuration of a display device 100 according to embodiments of the disclosure. What is identical or similar to those described with reference to FIG. 1 may be omitted from the following description or briefly described below.

Referring to FIG. 2, a display device 100 may include a display panel 110 and display driving circuits, as components for displaying images.

The display driving circuits are circuits for driving the display panel 110 and may include a data driving circuit DDC, a gate driving circuit GDC, and a display controller DTCR.

The display panel 110 may include a substrate SUB and a plurality of subpixels SP disposed on the substrate SUB. The display panel 110 may further include various types of signal lines to drive the plurality of subpixels SP.

The display device 100 according to embodiments of the disclosure may be a liquid crystal display device or a self-emission display device in which the display panel 110 emits light by itself. When the display device 100 according to the embodiments of the disclosure is a self-emission display device, each of the plurality of subpixels SP may include a light emitting element.

For example, the display device 100 according to embodiments of the disclosure may be an organic light emitting diode display in which the light emitting element is implemented as an organic light emitting diode (OLED). As another example, the display device 100 according to embodiments of the disclosure may be an inorganic light emitting display device in which the light emitting element is implemented as an inorganic material-based light emitting diode. As another example, the display device 100 according to embodiments of the disclosure may be a quantum dot display device in which the light emitting element is implemented as a quantum dot which is self-emission semiconductor crystal.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors.

For example, various types of signal lines may include a plurality of data lines DL transferring data signals (also referred to as data voltages or image signals) and a plurality of gate lines GL transferring gate signals (also referred to as scan signals).

The plurality of data lines DL and the plurality of gate lines GL may cross each other. Each of the plurality of data lines DL may be disposed while extending in a first direction. Each of the plurality of gate lines GL may be disposed while extending in a second direction. Here, the first direction may be a column direction and the second direction may be a row direction. The first direction may be the row direction, and the second direction may be the column direction.

The data driving circuit DDC is a circuit for driving the plurality of data lines DL, and may output data signals to the plurality of data lines DL. The gate driving circuit GDC is a circuit for driving the plurality of gate lines GL, and may output gate signals to the plurality of gate lines GL.

The display controller DCTR is a device for controlling the data driving circuit DDC and the gate driving circuit GDC and may control driving timings for the plurality of data lines DL and driving timings for the plurality of gate lines GL.

The display controller DCTR may supply a data driving control signal DCS to the data driving circuit DDC to control the data driving circuit GDC and may supply a gate driving control signal GCS to the gate driving circuit GDC to control the gate driving circuit GDC.

The display controller DCTR may receive input image data from the host system HSYS and supply image data DATA to the data driving circuit DDC based on the input image data.

The data driving circuit DDC may receive digital image data DATA from the display controller DCTR and may convert the received image data DATA into analog data signals and output the analog data signals to the plurality of data lines DL.

The gate driving circuit GDC may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

For example, the data driving circuit DDC may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The gate driving circuit GDC may be connected with the display panel 110 by TAB method or connected to a bonding pad of the display panel 110 by a COG or COP method or may be connected with the display panel 110 according to a COF method. Alternatively, the gate driving circuit GDC may be formed in a gate in panel (GIP) type, in the non-display area NDA of the display panel 110. The gate driving circuit GDC may be disposed on the substrate or may be connected to the substrate. In other words, the gate driving circuit GDC that is of a GIP type may be disposed in the non-display area NDA of the substrate. The gate driving circuit GDC that is of a chip-on-glass (COG) type or chip-on-film (COF) type may be connected to the substrate.

Meanwhile, at least one of the data driving circuit GDC and the gate driving circuit GDC may be disposed in the display area DA of the display panel 110. For example, at least one of the data driving circuit DDC and the gate driving circuit GDC may be disposed not to overlap the subpixels SP or to overlap all or some of the subpixels SP.

The data driving circuit DDC may be connected to one side (e.g., an upper or lower side) of the display panel 110. Depending on the driving scheme or the panel design scheme, data driving circuits DDC may be connected with both the sides (e.g., both the upper and lower sides) of the display panel 110, or two or more of the four sides of the display panel 110.

The gate driving circuit GDC may be connected to one side (e.g., a left or right side) of the display panel 110. Depending on the driving scheme or the panel design scheme, gate driving circuits GDC may be connected with both the sides (e.g., both the left and right sides) of the display panel 110, or two or more of the four sides of the display panel 110.

The display controller DCTR may be implemented as a separate component from the data driving circuit DDC, or the display controller DCTR and the data driving circuit DDC may be integrated into an integrated circuit (IC).

The display controller DCTR may be a timing controller used in typical display technology, a control device that may perform other control functions as well as the functions of the timing controller, or a control device other than the timing controller, or may be a circuit in the control device. The display controller DCTR may be implemented as various circuits or electronic components, such as an integrated circuit (IC), a field programmable gate array (FPGA), an application specific integrated circuit (ASIC), or a processor.

The display controller DCTR may be mounted on a printed circuit board or a flexible printed circuit and may be electrically connected with the data driving circuit DDC and the gate driving circuit GDC through the printed circuit board or the flexible printed circuit.

The display controller DCTR may transmit/receive signals to/from the data driving circuit DDC according to one or more predetermined interfaces. The interface may include, e.g., a low voltage differential signaling (LVDS) interface, an embedded clock point-point interface (EPI) interface, and a serial peripheral interface (SPI).

To provide a touch sensing function as well as an image display function, the display device 100 according to embodiments of the disclosure may include a touch sensor and a touch sensing circuit that senses the touch sensor to detect whether a touch occurs by a touch object, such as a finger or pen, or the position of the touch.

The touch sensing circuit may include a touch driving circuit TDC that drives and senses the touch sensor and generates and outputs touch sensing data and a touch controller TCTR that may detect an occurrence of a touch or the position of the touch using touch sensing data.

The touch sensor may include a plurality of touch electrodes. The touch sensor may further include a plurality of touch lines for electrically connecting the plurality of touch electrodes and the touch driving circuit TDC.

The touch sensor may be present in a touch panel form outside the display panel 110 or may be present inside the display panel 110. When the touch panel, in the form of a touch panel, exists outside the display panel 110, the touch panel is referred to as an external type. When the touch sensor is of the external type, the touch panel and the display panel 110 may be separately manufactured or may be combined during an assembly process. The external-type touch panel may include a touch panel substrate and a plurality of touch electrodes on the touch panel substrate.

When the touch sensor is present inside the display panel 110, the touch sensor may be formed on the substrate SUB, together with signal lines and electrodes related to display driving, during the manufacturing process of the display panel 110.

The touch driving circuit TDC may supply a touch driving signal to at least one of the plurality of touch electrodes and may sense at least one of the plurality of touch electrodes to generate touch sensing data.

The touch sensing circuit may perform touch sensing in a self-capacitance sensing scheme or a mutual-capacitance sensing scheme.

When the touch sensing circuit performs touch sensing in the self-capacitance sensing scheme, the touch sensing circuit may perform touch sensing based on capacitance between each touch electrode and the touch object (e.g., finger or pen). According to the self-capacitance sensing scheme, each of the plurality of touch electrodes may serve both as a driving touch electrode and as a sensing touch electrode. The touch driving circuit TDC may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between the touch electrodes. According to the mutual-capacitance sensing scheme, the plurality of touch electrodes are divided into driving touch electrodes and sensing touch electrodes. The touch driving circuit TDC may drive the driving touch electrodes and sense the sensing touch electrodes.

The touch driving circuit TDC and the touch controller TCTR included in the touch sensing circuit may be implemented as separate devices or as a single device. The touch driving circuit TDC and the data driving circuit DDC may be implemented as separate devices or as a single device.

The display device 100 may further include a power supply circuit for supplying various types of power to the display driver integrated circuit and/or the touch sensing circuit.

The display device 100 according to embodiments of the disclosure may be a mobile terminal, such as a smart phone or a tablet, or a monitor or television (TV) in various sizes but, without limited thereto, may be a display in various types and various sizes capable of displaying information or images.

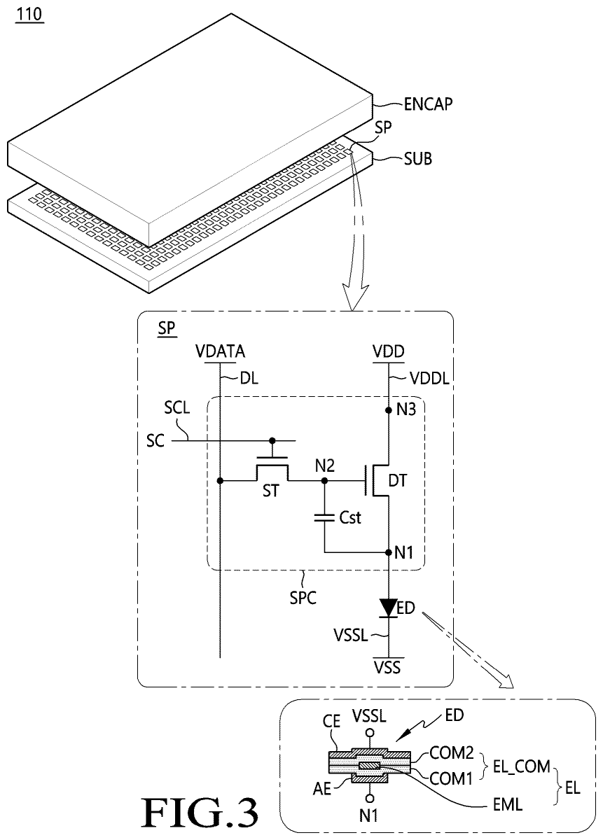

FIG. 3 illustrates an example display panel 110 according to an embodiment of the disclosure. What is identical or similar to those described in connection with FIGS. 1 and 2 may be omitted or briefly described below.

Referring to FIG. 3, the display panel 110 may include a substrate SUB where a plurality of subpixels SP are disposed and an encapsulation layer ENCAP on the substrate SUB. The encapsulation layer ENCAP may also be referred to as an encapsulation substrate or an encapsulation unit.

Referring to FIG. 3, when the display device 100 according to embodiments of the disclosure is a self-luminous display device, each of the plurality of subpixels SP disposed on the substrate SUB may include a light emitting element ED and a subpixel circuit SPC for driving the light emitting element ED.

Referring to FIG. 3, the subpixel circuit SPC may include a plurality of transistors for driving the light emitting element ED and at least one capacitor. In the disclosure, the subpixel circuit SPC may drive the light emitting element ED by supplying a driving current to the light emitting element ED at a predetermined timing. The light emitting element ED may be driven by a driving current to emit light.

The plurality of transistors may include a driving transistor DT for driving the light emitting element ED and a scan transistor ST that is turned on or off according to the scan signal SC.

The driving transistor DT may supply a driving current to the light emitting element ED.

The scan transistor ST may be configured to control the electrical state of a corresponding node in the subpixel circuit SPC or to control the state or operation of the driving transistor DT.

The at least one capacitor may include a storage capacitor Cst for maintaining a constant voltage during a frame.

To drive the subpixel SP, a data signal VDATA as an image signal and a scan signal SC as a gate signal may be applied to the subpixel SP. Further, for driving the subpixel SP, a common driving voltage including the first common driving voltage VDD and the second common driving voltage VSS may be applied to the subpixel SP.

The light emitting element ED may include a first electrode AE, a second electrode CE, and an intermediate layer EL. The intermediate layer EL may be disposed between the first electrode AE and the second electrode CE.

For example, the first electrode AE may be a pixel electrode disposed in each subpixel SP, and the second electrode CE may be a common electrode commonly disposed in all the subpixels SP. For example, the first electrode AE may be an anode electrode, and the second electrode CE may be a cathode electrode. As another example, the first electrode AE may be a cathode electrode, and the second electrode CE may be an anode electrode. For convenience of description, an example is described in which the first electrode AE is an anode electrode, and the second electrode CE is a cathode electrode.

When the light emitting element ED is an organic light emitting element, the intermediate layer EL may include a light emitting layer EML, a first common intermediate layer COM1 between the first electrode AE and the light emitting layer EML, and a second common intermediate layer COM2 between the light emitting layer EML and the second electrode CE. The first common intermediate layer COM1 and the second common intermediate layer COM2 may be collectively referred to as a common intermediate layer EL_COM.

The light emitting layer EML may be disposed for each subpixel SP. The common intermediate layer EL_COM may be disposed commonly across a plurality of subpixel SP.

The light emitting layer EML may be disposed for each light emitting area, and the common intermediate layer EL_COM may be commonly disposed over the plurality of light emitting areas and the non-light emitting area.

For example, the first common intermediate layer COM1 may include at least one of a hole injection layer HIL and a hole transport layer HTL. The second common intermediate layer COM2 may include at least one of an electron transport layer ETL and an electron injection layer EIL.

The hole injection layer may inject holes from the first electrode AE to the hole transport layer, and the hole transport layer may transport holes to the light emitting layer EML. The electron injection layer may inject electrons from the second electrode CE to the electron transport layer, and the electron transport layer may transport electrons to the light emitting layer EML.

For example, the second electrode CE may be electrically connected to the second common driving voltage line VSSL. The second common driving voltage VSS may be applied to the second electrode CE through the second common driving voltage line VSSL. The first electrode AE may be electrically connected directly or indirectly (through another transistor) to the first node N1 of the driving transistor DT of each subpixel SP. In the disclosure, “the second common driving voltage VSS” may also be referred to as a “base voltage”, and “the second common driving voltage line VSSL” may also be referred to as a “low-potential power voltage line” or “base voltage line”.

Each light emitting element ED may include portions where the first electrode AE, the light emitting layer EML in the intermediate layer LE, and the second electrode CE overlap. A predetermined light emitting area may be formed by each light emitting element ED. For example, the light emitting area of each light emitting element ED may include an overlapping area of the first electrode AE, the light emitting layer EML in the intermediate layer EL, and the second electrode CE.

For example, the light emitting element ED may be an organic light emitting diode (OLED), an inorganic light emitting diode (LED), or a quantum dot light emitting element. For example, when the light emitting element ED is an organic light emitting diode (OLED), the intermediate layer EL of the light emitting element ED may include an intermediate layer EL including an organic material.

The driving transistor DT may be a driving transistor for supplying a driving current to the light emitting element ED. The driving transistor DT may be connected between the first common driving voltage line VDDL and the light emitting element ED.

The driving transistor DT may include a first node N1, a second node N2, and a third node N3. The first node N1 may be electrically connected to the light emitting element ED. A data signal VDATA may be applied to the second node N2. A first common driving voltage VDD may be applied to the third node N3 from the first common driving voltage line VDDL.

In the driving transistor DT, the second node N2 may be a gate node, the first node N1 may be a source node or a drain node, and the third node N3 may be a drain node or a source node. Hereinafter, for convenience of description, an example is described in which in the driving transistor DT, the second node N2 may be a gate node (or gate electrode), the first node N1 may be a source node (or source electrode), and the third node N3 may be a drain node (or drain electrode), but embodiments of the disclosure are not limited thereto.

The scan transistor ST included in the subpixel circuit SPC illustrated in FIG. 3 may be a switching transistor for transferring the data signal VDATA, which is an image signal, to the second node N2, which is the gate node of the driving transistor DT.

The scan transistor ST may be controlled to be turned on and off by the scan signal SC, which is a gate signal applied through the scan line SCL, which is a type of the gate line GL, to control electrical connection between the second node N2 of the driving transistor DT and the data line DL. The drain electrode or source electrode of the scan transistor ST may be electrically connected to the data line DL. The source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and second node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The capacitor Cst may be an external capacitor designed to be outside the driving transistor DT, but not a parasite capacitor (e.g., Cgs or Cgd) which is an internal capacitor that may be present between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

When the display panel 110 has a top emission structure, at least a portion of the subpixel circuit SPC may overlap at least a portion of the light emitting element ED in a vertical direction. Accordingly, the area of the emission area may increase and the aperture ratio may increase.

When the display panel 110 has a bottom emission structure, the subpixel circuit SPC may not overlap the light emitting element ED in the vertical direction.

As illustrated in FIG. 3, the subpixel circuit SPC may have a 2T (Transistor) 1C (Capacitor) structure including two transistors DT and ST and one capacitor Cst. In some cases, the subpixel circuit SPC may further include one or more transistors or may further include one or more capacitors.

For example, the subpixel circuit SPC may have an 8T1C structure including 8 transistors and 1 capacitor. As another example, the subpixel circuit SPC may have a 6T2C structure including 6 transistors and 2 capacitors. As another example, the subpixel circuit SPC may have a 7T1C structure including 7 transistors and 1 capacitor. Embodiments of the disclosure are not limited thereto.

Depending on the structure of the subpixel circuit SPC, the type and number of gate lines or the gate signals supplied to the subpixel SP may vary. Further, the type and the number of common driving voltages supplied to the subpixel SP may vary depending on the structure of the subpixel circuit SPC.

Referring to FIG. 3, since the circuit elements (e.g., the light emitting element ED implemented as an organic light emitting diode (OLED) including an organic material) in each subpixel SP are vulnerable to external moisture or oxygen, the encapsulation layer ENCAP for preventing external moisture or oxygen from penetrating into the circuit elements (e.g., the light emitting element ED) may be disposed on the display panel 110.

The encapsulation layer ENCAP may be configured in various forms so that the light emitting elements ED do not contact moisture or oxygen. For example, the encapsulation layer ENCAP may be constituted of two or more layers in which organic layers and inorganic layers are alternately stacked, but embodiments of the disclosure are not limited thereto.

Referring to FIG. 3, a display device 100 according to embodiments of the disclosure may include a touch sensor layer including a plurality of sensor electrodes to sense the user's touch, a touch driving circuit configured to sense the plurality of sensor electrodes, and a touch controller configured to determine the presence or absence of a touch or touch coordinates using the sensing result (touch sensing data) of the touch driving circuit.

The touch sensor layer may be embedded in the display panel 110. For example, the touch sensor layer may be disposed on the encapsulation layer ENCAP in the display panel 110.

The display panel 110 may further include a plurality of touch pads electrically connected to the touch driving circuit and a plurality of touch lines for electrically connecting the plurality of sensor electrodes included in the touch sensor layer to the plurality of touch pads connected to the touch driving circuit.

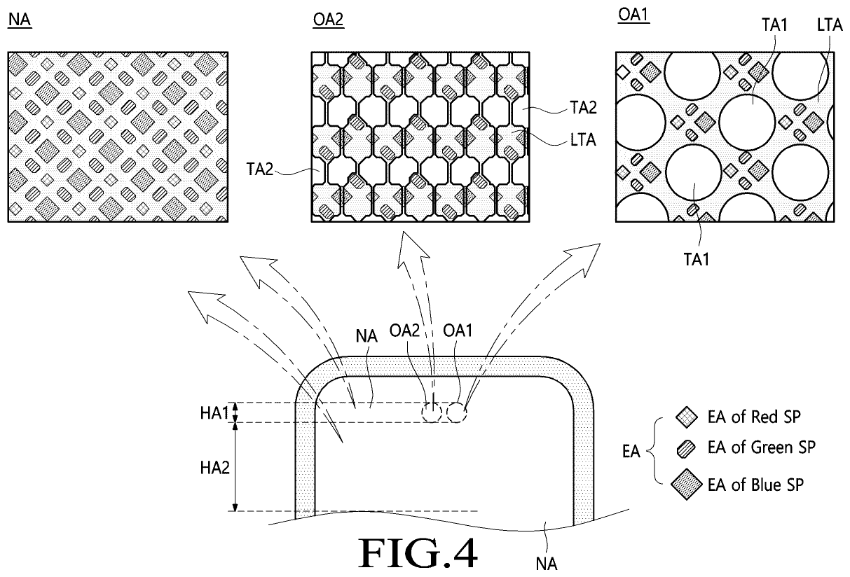

FIG. 4 is a view illustrating an example arrangement of subpixels SP in three areas NA, OA1, and OA2 included in a display area DA of a display device 100 according to embodiments of the disclosure. What is identical or similar to those described with reference to FIGS. 1 to 3 is omitted from the following description or briefly described below.

Referring to FIG. 4, a plurality of subpixels SP may be disposed in the normal area NA, the first optical area OA1, and the second optical area OA2 included in the display area DA.

For example, the plurality of subpixels SP may include a red subpixel Red SP emitting red light, a green subpixel Green SP emitting green light, and a blue subpixel Blue SP emitting blue light.

Accordingly, each of the normal area NA, the first optical area OA1, and the second optical area OA2 may include emission areas EA of the red subpixels Red SP, emission areas EA of the green subpixels Green SP, and emission areas EA of the blue subpixels Blue SP.

Referring to FIG. 4, the normal area NA may not include a light transmission structure, but may include light emission areas EA.

In this case, the optical areas OA1 and OA2 should not only include the emission areas EA, but also include a light transmission structure. The optical areas OA1 and OA2 may include transmissive areas TA1 and TA2 and a low transmissive area LTA. For example, a first optical area OA1 may include first transmissive areas TA1 and a low transmissive area LTA, and a second optical area OA2 may include second transmissive areas TA2 and a low transmissive area LTA.

In the optical areas OA1 and OA2, the low transmissive area LTA, except for the transmissive areas TA1 and TA2, may include a plurality of emission areas EA. For example, the first optical area OA1 may include emission areas EA and first transmissive areas TA1, and the second optical area OA2 may include emission areas EA and second transmissive areas TA2.

The low transmissive area LTA and the transmissive areas TA1 and TA2 may be distinguished based on whether they may transmit light. In other words, the low transmissive area LTA may be areas through which light cannot pass, and the transmissive areas TA1 and TA2 may be areas through which light can pass.

Further, the low transmissive area LTA and the transmissive areas TA1 and TA2 may be distinguished depending on the presence or absence of a specific metal layer CE. For example, a second electrode CE may be formed in the low transmissive area LTA, and a second electrode CE may not be formed in the transmissive area TA. A light shield layer LSL may be formed in the low transmissive area LTA, and a light shield layer may not be formed in the transmissive areas TA1 and TA2.

Further, a plurality of pixel circuits SPC for driving the plurality of light emitting elements ED may be disposed in the low transmissive area LTA.

Meanwhile, the low transmissive area LTA in the optical areas OA1 and OA2 may be an area through which light is not transmitted. Alternatively, the low transmissive area LTA in the optical areas OA1 and OA2 may be an area through which light is transmitted at low transmittance (low transmission ratio). In the optical areas OA1 and OA2, the transmittance (transmission ratio) of the low transmissive area LTA may be lower than that of the transmissive area TA. However, the transmittance of the low transmissive area LTA in the optical areas OA1 and OA2 may be higher than that of the normal area NA.

Since the first optical area OA1 includes first transmissive areas TA1 and the second optical area OA2 includes second transmissive areas TA2, both the first optical area OA1 and the second optical area OA2 are areas through which light may pass.

The transmittance (degree of transmission) of the first optical area OA1 and the transmittance (degree of transmission) of the second optical area OA2 may be substantially the same. In the disclosure, when A is substantially the same as B, it may mean that A and B are regarded as the same considering a tiny difference due to a processing error.

In this case, the first transmissive area TA1 of the first optical area OA1 and the second transmissive area TA2 of the second optical area OA2 may have substantially the same shape or size. Alternatively, even though the first transmissive area TA1 of the first optical area OA1 and the second transmissive area TA2 of the second optical area OA2 have different shapes or sizes, the ratio of the first transmissive area TA1 in the first optical area OA1 and the ratio of the second transmissive area TA2 in the second optical area OA2 may be substantially the same.

However, without limitations thereto, the transmittance (degree of transmission) of the first optical area OA1 and the transmittance (degree of transmission) of the second optical area OA2 may be different from each other.

In this case, the first transmissive area TA1 of the first optical area OA1 and the second transmissive area TA2 of the second optical area OA2 may have different shapes or sizes. Alternatively, even though the first transmissive area TA1 of the first optical area OA1 and the second transmissive area TA2 of the second optical area OA2 have substantially the same shape or size, the ratio of the first transmissive area TA1 in the first optical area OA1 and the ratio of the second transmissive area TA2 in the second optical area OA2 may be different from each other.

For example, if the first optical electronic device 11 overlapping the first optical area OA1 is a camera and the second optical electronic device 12 overlapping the second optical area OA2 is a detection sensor, the camera may require a larger amount of light than the detection sensor.

Therefore, the transmittance (degree of transmission) of the first optical area OA1 may be higher than the transmittance (degree of transmission) of the second optical area OA2.

In this case, the first transmissive area TA1 of the first optical area OA1 may have a size larger than that of the second transmissive area TA2 of the second optical area OA2. Alternatively, even though the first transmissive area TA1 of the first optical area OA1 and the second transmissive area TA2 of the second optical area OA2 substantially have the same size, a ratio of the first transmissive area TA1 in the first optical area OA1 may be larger than a ratio of the second transmissive area TA2 in the second optical area OA2.

Meanwhile, as illustrated in FIG. 4, the first transmissive area TA1 of the first optical area OA1 may be circular in plan view, but the planar structure of the first transmissive area TA1 according to embodiments of the disclosure is not limited thereto.

For example, the shape of the first transmissive area TA1 of the first optical area OA1 may be octagonal in plan view. As another example, it may be elliptical or polygonal.

As such, it is possible to adjust the area of the emission area of the first optical area OA1 while adjusting the transmittance of the first transmissive area TA1 by changing the shape of the first transmissive area TA1.

Hereinafter, for convenience of description, the case where the transmittance (degree of transmission) of the first optical area OA1 is higher than the transmittance (degree of transmission) of the second optical area OA2 is described as an example.

Further, as illustrated in FIG. 4, in embodiments of the disclosure, the transmissive area TA1 and TA2 may also be referred to as a transparent area, and the transmittance may also be referred to as transparency.

Further, as illustrated in FIG. 4, in embodiments of the disclosure, it is assumed that the first optical area OA1 and the second optical area OA2 are positioned at the upper end of the display area DA of the display panel 110 and are disposed side by side.

Referring to FIG. 4, a horizontal display area where the first optical area OA1 and the second optical area OA2 are disposed is referred to as a first horizontal display area HA1, and a horizontal display area where the first optical area OA1 and the second optical area OA2 are not disposed is referred to as a second horizontal display area HA2.

Referring to FIG. 4, the first horizontal display area HA1 may include a normal area NA, a first optical area OA1, and a second optical area OA2.

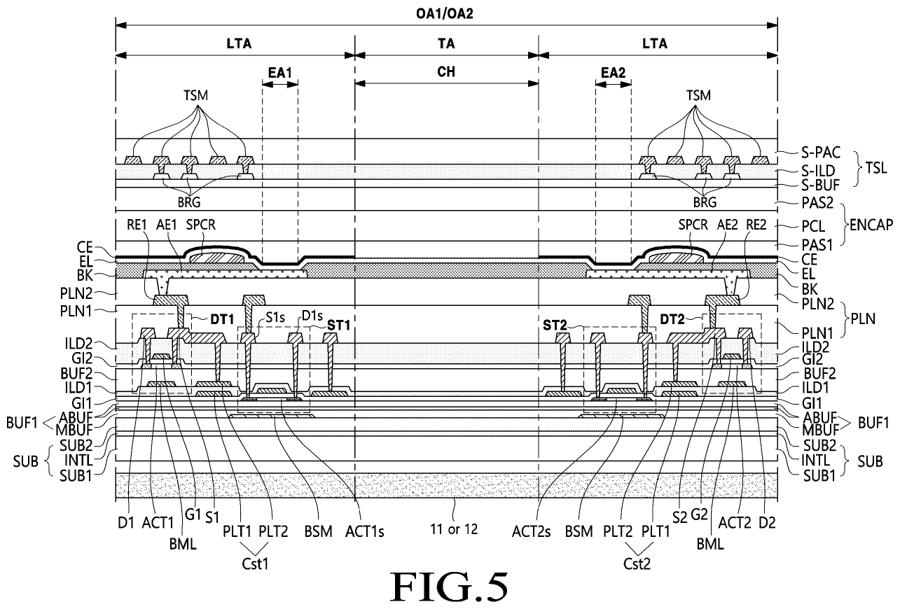

FIG. 5 is an example cross-sectional view illustrating an optical area OA1 or OA2 of a display panel 110 according to embodiments of the disclosure. Those identical or similar to what has been described with reference to FIGS. 1 to 4 are omitted from the following description or are briefly described.

Referring to FIG. 5, a first light emitting element ED1 and a second light emitting element ED2 may be disposed in the optical areas OA1 and OA2. The area where the first light emitting element ED1 and the second light emitting element ED2 are disposed is a low transmissive area LTA, and a transmissive area TA may be present between the first light emitting element ED1 and the second light emitting element ED2. For example, a transmissive area TA may be present between the first emission area EA1 by the first light emitting element ED1 and the second emission area EA2 by the second light emitting element ED2.

Referring to FIG. 5, the pixel circuit unit SPC for driving the first light emitting element ED1 may be configured to drive the first light emitting element ED1 and may be disposed to overlap the whole or part of the first light emitting element ED1 in the optical areas OA1 and OA2. The pixel circuit unit SPC for driving the second light emitting element ED2 may be configured to drive the second light emitting element ED2 and may be disposed to overlap the whole or part of the second light emitting element ED2 in the optical areas OA1 and OA2.

The pixel circuit SPC for driving the first light emitting element ED1 may include a first driving transistor DT1, a first scan transistor ST1, and a first storage capacitor Cst1. The pixel circuit SPC for driving the second light emitting element ED2 may include a second driving transistor DT2, a second scan transistor ST2, and a second storage capacitor Cst2. Since the pixel circuit SPC for driving the first light emitting element ED1 and the pixel circuit SPC for driving the second light emitting element ED2 include substantially the same components, the pixel circuit SPC for driving the first light emitting element ED1 is described in detail.

Referring to FIG. 5, when viewed in a vertical structure, the display panel 110 may include a transistor forming part, a light emitting element forming part, and an encapsulation part.

The transistor forming part may include a substrate SUB, a first buffer layer BUF1 on the substrate SUB, and various transistors DT1 and ST, storage capacitor Cst, and various electrodes or signal lines formed on the first buffer layer BUF.

A lower shield metal BSM may be disposed on the substrate SUB. The lower shield metal BSM may be positioned under the first active layer ACT1s of the first scan transistor ST1.

The first buffer layer BUF1 may be a single film or multi-film structure. When the first buffer layer BUF1 is formed in a multi-film structure, the first buffer layer BUF1 may include a multi-buffer layer MBUF and an active buffer layer ABUF.

Various transistors DT1 and ST1, storage capacitor Cst, and various electrodes or signal lines may be formed on the first buffer layer BUF1.

For example, the transistors DT1 and ST1 formed on the first buffer layer BUF1 are formed of the same material and on the same layer. Alternatively, as illustrated in FIG. 5, among the transistors DT1 and ST1, the first driving transistor DT1 and the first scan transistor ST1 may be formed of different materials and may be positioned on different layers.

The formation of the first driving transistor DT1 and the first scan transistor ST1 is described below.

The first scan transistor ST1 may include a first active layer ACT1s, a first gate electrode G1s, a first source electrode S1s, and a first drain electrode D1s.

The first driving transistor DT1 may include a first active layer ACT1, a first gate electrode G1, a first source electrode S1s, and a first drain electrode D1.

The first active layer ACT1 of the first driving transistor DT1 may be positioned higher than the first active layer ACT1s of the first scan transistor ST1.

A first buffer layer BUF1 may be disposed under the first active layer ACT1s of the first scan transistor ST1, and a second buffer layer BUF2 may be disposed under the first active layer ACT1 of the first driving transistor DT1.

In other words, the first active layer ACT1s of the first scan transistor ST1 may be positioned on the first buffer layer BUF1, and the first active layer ACT1 of the first driving transistor DT1 may be positioned on the second buffer layer BUF2. Here, the second buffer layer BUF2 may be positioned higher than the first buffer layer BUF1.

The first active layer ACT1s of the first scan transistor ST1 may be disposed on the first buffer layer BUF1, and a first gate insulation film GI1 may be formed on the first active layer ACT1s of the first scan transistor ST1. The first gate electrode G1s of the first scan transistor ST1 may be disposed on the first gate insulation film GI1, and a first interlayer insulation film ILD1 may be disposed on the first gate electrode G1s of the first scan transistor ST1.

Here, the first active layer ACT1s of the first scan transistor ST1 may include a first channel area overlapping the first gate electrode G1s, a first source connection area positioned on one side of the first channel area, and a channel area, and a first drain connection area positioned on the other side of the channel area.

A second buffer layer BUF2 may be disposed on the first interlayer insulation film ILD1.

The first active layer ACT1 of the first driving transistor DT1 may be disposed on the second buffer layer BUF2, and a second gate insulation film GI2 may be disposed on the first active layer ACT1. The first gate electrode G1 of the first driving transistor DT1 may be disposed on the second gate insulation film GI2, and a second interlayer insulation film ILD2 may be disposed on the first gate electrode G1.

Here, the first active layer ACT1 of the first driving transistor DT1 may include a second channel area overlapping the first gate electrode G1, a first source connection area positioned on one side of the second channel area, and a second drain connection area positioned on the other side of the channel area.

The first source electrode S1s and the first drain electrode D1s of the first scan transistor ST1 may be disposed on the second interlayer insulation film ILD2. Further, the first source electrode S1s and the first drain electrode D1 of the first driving transistor DT1 may be disposed on the second interlayer insulation film ILD2.

The first source electrode S1s and the first drain electrode D1s of the first scan transistor ST1 may be connected with the first source connection area and the first drain connection area, respectively, of the first active layer ACT1s through the through holes of the second interlayer insulation film ILD2, the second gate insulation film GI2, the second buffer layer BUF2, the first interlayer insulation film ILD1, and the first gate insulation film GI1.

The first source electrode S1s and the second drain electrode D21 of the first driving transistor DT1 may be connected with the second source connection area and the second drain connection area, respectively, of the first active layer ACT1 through the through holes in the second interlayer insulation film ILD2 and the second gate insulation film GI2.

Referring to FIG. 5, the first storage capacitor Cst1 included in the first pixel circuit SPC1 may include a first capacitor electrode PLT1 and a second capacitor electrode PLT2.

The first capacitor electrode PLT1 may be electrically connected to the first gate electrode G1 of the first driving transistor DT1, and the second capacitor electrode PLT2 may be electrically connected to the first source electrode S1 of the first driving transistor DT1.

Meanwhile, referring to FIG. 5, a lower metal BML may be disposed under the first active layer ACT1 of the first driving transistor DT1. The lower metal BML may overlap the whole or part of the first active layer ACT1.

For example, the lower metal BML may be electrically connected to the first gate electrode G1. As another example, the lower metal BML may serve as a light shield to block the light introduced from thereunder. In this case, the lower metal BML may be electrically connected to the first source electrode S1.

The first driving transistor DT1 and the first scan transistor ST1 may be disposed in the low transmissive area LTA.

Referring to FIG. 5, the display panel 110 may include at least one planarization layer PLN disposed on the first driving transistor DT1 and the first scan transistor ST1.

For example, referring to FIG. 5, at least one planarization layer PLN may include a first planarization layer PLN1. The first planarization layer PLN1 may be disposed on the first source electrode S1 and the first drain electrode D of the first driving transistor DT1, and on the first source electrode Sls and the first drain electrode D1s of the first scan transistor ST1.

Referring to FIG. 5, a first relay electrode RE1 may be disposed on the first planarization layer PLN1.

Here, the first relay electrode RE1 may be an electrode that relays an electrical connection between the first source electrode S1 of the first driving transistor DT1 and the first electrode AE1 of the first light emitting element ED1. The first relay electrode RE1 may be electrically connected to the first source electrode S1 of the first driving transistor DT1 through a hole in the first planarization layer PLN1.

Referring to FIG. 5, the first relay electrode RE1 may be disposed in the low transmissive area LTA.

Referring to FIG. 5, the planarization layer PLN disposed on the display panel 110 may further include a second planarization layer PLN2 on the first planarization layer PLN1. For example, the second planarization layer PLN2 may be disposed while covering the first relay electrode RE1 positioned on the first planarization layer PLN1.

According to the example of FIG. 5, although the planarization layer PLN includes the first planarization layer PLN1 and the second planarization layer PLN2, in some cases, the planarization layer PLN may further include one or more planarization layers.

Referring to FIG. 5, a light emitting element forming part may be positioned on the second planarization layer PNL2.

Referring to FIG. 5, the light emitting element forming part may include a first light emitting element ED1 and a second light emitting element ED2 formed on the second planarization layer PNL2. The first light emitting element ED1 and the second light emitting element ED2 may be disposed in the low transmissive area TLA.

Referring to FIG. 5, the first light emitting element ED1 may be configured in an area where the first electrode AE1, the intermediate layer EL, and the second electrode CE overlap.

Referring to FIG. 5, the first electrode AE1 may be disposed on the second planarization layer PLN2. The first electrode AE1 may be connected to the first relay electrode RE1 through the hole of the second planarization layer PLN2.

Referring to FIG. 5, a bank BK may be disposed on the first electrode AE1. The bank BK may include the plurality of bank holes, and a portion of the first electrode AE1 may be exposed through the plurality of bank holes. In other words, the plurality of bank holes formed in the bank BK may overlap a portion of the first electrode AE1.

Referring to FIG. 5, an intermediate layer EL may be disposed on the bank BK. The intermediate layer EL may contact a portion of the first electrode AE1 through the plurality of bank holes.

Referring to FIG. 5, at least one spacer SPCR may be present between the intermediate layer EL and the bank BK.

Referring to FIG. 5, the second electrode CE may be disposed on the intermediate layer EL. The cathode electrode CE may not include a plurality of cathode holes CH or may include a plurality of cathode holes CH. When the cathode electrode CE includes a plurality of cathode holes CH, the plurality of cathode holes CH formed in the cathode electrode CE may be positioned to correspond to the transmissive area TA in the optical areas OA1 and OA2.

The bank hole formed in the bank BK may not overlap the cathode hole CH.

The upper surface of the banks BK positioned under the plurality of cathode holes CH may be in a flat state without being recessed or etched. In other words, at the point where the cathode hole CH is present, the bank BK is not recessed or perforated. Accordingly, at the point where the cathode hole CH is present, the second planarization layer PLN2 and the first planarization layer PLN1 positioned under the bank BK are also not recessed or perforated.

The flat upper surface of the bank BK positioned under the plurality of cathode holes CH may mean that the insulation layer, the metal pattern (electrode, line, or the like), or the light emitting layer EL positioned under the cathode electrode CE is not damaged by the process of forming the plurality of cathode holes CH in the cathode electrode CE.

The process of forming the plurality of cathode holes CH in the cathode electrode CE is briefly described below. A specific mask pattern is deposited in positions where a plurality of cathode holes CH are to be formed, and a cathode electrode material is deposited thereon. Accordingly, the cathode electrode material may be deposited only in an area without the specific mask pattern, so that the cathode electrode CE having a plurality of cathode holes CH may be formed. For example, the specific mask pattern may include an organic material. The cathode electrode material may include a magnesium-silver (Mg—Ag) alloy.

Meanwhile, after the cathode electrode CE having the plurality of cathode holes CH is formed, the display panel 110 may be in a state in which the specific mask pattern is completely removed or in a state in which the whole or part of the specific mask pattern remains.

Referring to FIG. 5, an encapsulation part may be positioned on the second electrode CE. The encapsulation part may include an encapsulation layer ENCAP formed on the second electrode CE.

Referring to FIG. 5, the encapsulation layer ENCAP may be a layer that prevents penetration of moisture or oxygen into the light emitting elements ED1 and ED2 disposed under the encapsulation layer ENCAP. In particular, the encapsulation layer ENCAP may prevent penetration of moisture or oxygen into the intermediate layer EL, which may include an organic film. Here, the encapsulation layer ENCAP may be composed of a single film or a multi-film structure.

Referring to FIG. 5, the encapsulation layer ENCAP may include a first encapsulation layer PAS1, a second encapsulation layer PCL, and a third encapsulation layer PAS2.

For example, the first encapsulation layer PAS1 and the third encapsulation layer PAS2 may be inorganic films, and the second encapsulation layer PCL may be an organic layer. As the second encapsulation layer PCL is formed of an organic film, the second encapsulation layer PCL may serve as a planarization layer.

Meanwhile, the display panel 110 according to embodiments of the disclosure may include a touch sensor. In this case, the display panel 110 according to embodiments of the disclosure may include a touch sensor layer TSL formed on the encapsulation layer ENCAP.

Referring to FIG. 5, the touch sensor layer TSL may include touch sensor metals TSM and bridge metals BRG and may further include insulation film components, such as a sensor buffer layer S-BUF, a sensor interlayer insulation film S-ILD, and a sensor protection layer S-PAC. Here, the sensor interlayer insulation film S-ILD may include one or more insulation films.

The sensor buffer layer S-BUF may be disposed on the encapsulation layer ENCAP. The bridge metals BRG may be disposed on the sensor buffer layer S-BUF. The sensor interlayer insulation film S-ILD may be disposed on the bridge metals BRG.

The touch sensor metals TSM may be disposed on the sensor interlayer insulation film S-ILD. Some of the touch sensor metals TSM may be connected to the corresponding bridge metal BRG through a hole in the sensor interlayer insulation film S-ILD.

Referring to FIG. 5, the touch sensor metals TSM and the bridge metals BRG may be disposed in the optical bezel area OBA. The touch sensor metals TSM and the bridge metals BRG may be disposed not to overlap the emission areas EA1 and EA2 of the low transmissive area LTA.

The plurality of touch sensor metals TSM may configure one touch electrode (or one touch electrode line) and may be disposed in a mesh form and electrically connected. Some of the touch sensor metals TSM and some others of the touch sensor metals TSM may be electrically connected through a bridge metal BRG, configuring one touch electrode (or one touch electrode line).

The sensor protection layer S-PAC may be disposed while covering the touch sensor metals TSM and the bridge metals BRG.

Meanwhile, when the display panel 110 is of a type that incorporates touch sensors, at least a portion of the touch sensor metal TSM positioned on the encapsulation layer ENCAP in the display area DA may extend and be disposed along the outer inclined surface of the encapsulation layer ENCAP to electrically connect to a pad positioned further outside the outer inclined surface of the encapsulation layer ENCAP. Here, the pad may be disposed in the non-display area NDA and may be a metal pattern to which the touch driving circuit TDC is electrically connected.

The display panel 110 according to embodiments of the disclosure may further include a substrate SUB, a first buffer layer BUF1 disposed between the substrate SUB and the first scan transistor ST1, and a second buffer layer BUF2 disposed between the first scan transistor ST1 and the first driving transistor DT1.

The first active layer ACT1s of the first scan transistor ST1 and the first active layer ACT1 of the first driving transistor DT1 may comprise different semiconductor materials.

For example, the first active layer ACT1 of the first driving transistor DT1 may include an oxide semiconductor material. For example, the oxide semiconductor material may include indium gallium zinc oxide (IGZO), indium gallium zinc tin oxide (IGZTO), zinc oxide (ZnO), cadmium oxide (CdO), indium oxide (InO), zinc tin oxide (ZTO), and zinc indium tin oxide (ZITO).

For example, the first active layer ACT1s of the first scan transistor ST1 may include a different semiconductor material from the first active layer ACT1 of the first driving transistor DT1. For example, the first active layer ACT1s of the first scan transistor ST1 may include a silicon-based semiconductor material. For example, the silicon-based semiconductor material may include low-temperature polycrystalline silicon (LTPS) or the like.

Referring to FIG. 5, the second driving transistor DT2 may include a second active layer ACT2, a second gate electrode G2, a second source electrode S2, and a second drain electrode D2.

The second light emitting element ED2 may be formed in a portion where the first electrode AE2, the intermediate layer EL, and the second electrode CE overlap.

The second source electrode S2 of the second driving transistor DT2 may be connected to the first electrode AE2 through a second relay electrode RE2.

The second storage capacitor Cst2 may include a first capacitor electrode PLT1 and a second capacitor electrode PLT2.

The second source electrode S2 of the second driving transistor DT2 may be connected to the second capacitor electrode PLT2 of the second storage capacitor Cst2.

The second gate electrode G2 of the second driving transistor DT2 may be connected to the first capacitor electrode PLT1 of the second storage capacitor Cst2.

The active layer ACT2s of the second scan transistor ST2 may be positioned on the first buffer layer BUF1, and may be positioned lower than the second active layer ACT2 of the second driving transistor DT2.

The semiconductor material included in the active layer ACT2s of the second scan transistor ST2 may be different from the semiconductor material included in the second active layer ACT2 of the second driving transistor DT2. For example, the semiconductor material included in the second active layer ACT2 of the second driving transistor DT2 may be an oxide semiconductor material, and the semiconductor material included in the active layer ACT2s of the second scan transistor ST2 may be a silicon-based semiconductor material (e.g., low-temperature polycrystalline silicon (LTPS).

Referring to FIG. 5, the optical areas OA1 and OA2 may overlap the optical electronic device. The optical electronic device overlapping the optical area OA may be the first optical electronic device 11 and/or the second optical electronic device 12. For example, the optical electronic device may include a camera, an infrared sensor, or an ultraviolet sensor. For example, an optical electronic device may be a device that receives visible light and performs a predetermined operation, or may be a device that receives other rays (e.g., infrared rays, ultraviolet rays) than visible light and performs a predetermined operation.

Referring to FIG. 5, the cross-sectional structure of the normal area NA may be the same as that of the low transmissive area LTA.

Referring to FIG. 5, two or more light emitting elements ED may be disposed in the optical areas OA1 and OA2. For example, two or more light emitting elements ED may be disposed in the low transmissive area LTA in the optical area OA. Further, transistors DT and ST and storage capacitors Cst may be disposed in the optical area OA. For example, transistors DT and ST and storage capacitors Cst may be disposed in the low transmissive area LTA in the optical area OA.

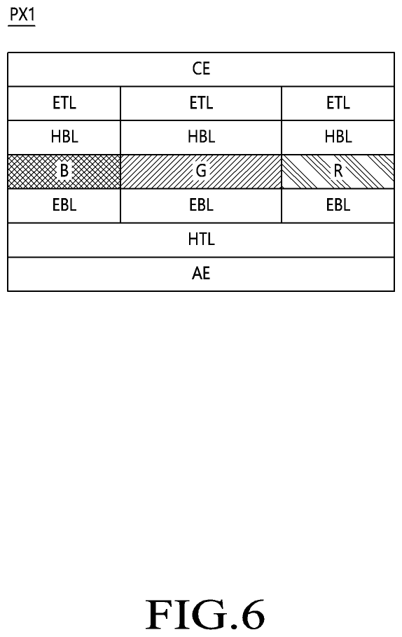

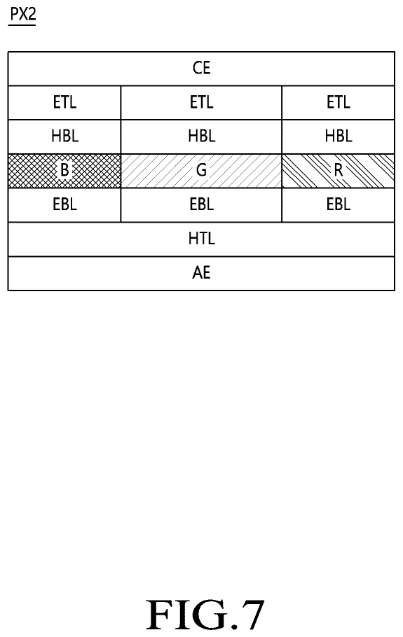

FIGS. 6 and 7 are example cross-sectional views illustrating light emitting elements disposed in a normal area of a display panel 110 according to embodiments of the disclosure. Those identical or similar to what has been described with reference to FIGS. 1 to 5 are omitted from the following description or are briefly described.

FIG. 6 is an example cross-sectional view illustrating light emitting elements disposed in the first pixel PX1 of the normal area, and FIG. 7 is an example cross-sectional view illustrating light emitting elements disposed in the second pixel PX2 of the optical area.

Referring to FIGS. 6 and 7, the light emitting element ED according to embodiments of the disclosure may include a red subpixel R, a green subpixel G, and a blue subpixel B that emit light of different colors on the substrate. The light emitting element ED may include a first electrode AE disposed on the substrate, a second electrode CE disposed to face the first electrode AE, and a light emitting layer EML formed between the first electrode AE and the second electrode CE.

The first electrode AE may be electrically connected to any one of the source electrode and the drain electrode through the contact hole formed in the insulation layer in the transistor including the source electrode, the drain electrode, the gate electrode, and the active layer.

The first electrode AE may be formed of a material having a relatively high work function. The first electrode AE may be formed of, e.g., a transparent conductive oxide such as indium tin oxide (ITO), indium zinc oxide (IZO), zinc oxide (ZnO), AI-doped zinc oxide (AZO), indium oxide (In₂O₃), or tin oxide (SnO₂), but the disclosure is not limited thereto.

As the second electrode CE, a metal, an alloy, an electrically conductive compound, or a mixture of two or more thereof having a relatively low work function may be used. For example, as the second electrode CE, a transmissive electrode may be obtained by forming a thin film of lithium (Li), magnesium (Mg), aluminum (Al), aluminum-lithium (Al—Li), calcium (Ca), magnesium-indium (Mg—In), magnesium-silver (Mg—Ag), or the like.

On the other hand, in order to obtain a top emitting device, a transmissive electrode using ITO and IZO may be formed, and various changes may be made thereto according to embodiments of the disclosure.

A capping layer (not illustrated) may be included on the second electrode CE to maximize light emission efficiency by enhancing optical characteristics. The capping layer may be formed of, e.g., a metal oxide layer, a metal nitride layer, or a metal oxynitride layer.

For example, it may be formed of MoOₓ (x=2˜4), Al₂O₃, Sb₂O₃, BaO, CdO, CaO, Ce₂O₃, CoO, Cu₂O, DyO, GdO, HfO₂, La₂O₃, Li₂O, MgO, NbO, NiO, Nd₂O₃, PdO, Sm₂O₃, ScO, SiO₂, SrO, Ta₂O₃, TiO, WO₃, VO₂, YbO, Y₂O₃, ZnO, ZrO, AlN, BN, NON, SiN, TaN, TiN, VN, YbN, ZrN, SiON, or AlON, or a mixture thereof, but is not limited thereto.

The light emitting layer EML may include a red light emitting layer R disposed in the red subpixel R, a green light emitting layer G disposed in the green subpixel G, and a blue light emitting layer B disposed in the blue subpixel B. In this case, the wavelength of the emitted light may increase in the order of the red light emitting layer R, the green light emitting layer G, and the blue light emitting layer B. The thickness of the light emitting layer EML may be 350 Å to 420 Å.

The light emitting layer EML may include a host HT and a dopant DP.

The host HT may include at least one of a p-type host pHT and an n-type host nHT.

In embodiments of the disclosure, a “p-type host” may mean a host material having a p-type property. The p-type property refers to the property of injecting or transporting holes at the high occupied molecular orbital (HOMO) energy level, i.e., the property of a material with high hole conductivity.

In embodiments of the disclosure, an “n-type host” refers to a host material having an n-type property. The n-type property refers to the property of injecting or transporting electrons to the lowest unoccupied molecular orbital (LUMO) energy level, i.e., the property of a material with high electron conductivity.

A charge balance between holes and electrons may be adjusted by adjusting the ratio of the p-type host pHT, the n-type host nHT, and the dopant DP included in the light emitting layer EML. By optimizing the position of the recombination zone through the adjustment of charge balance, the lifespan of the light emitting element may be enhanced. For example, in the light emitting layer EML, excitons may be generated between the p-type host pHT and the n-type host nHT, and after the excitons are delivered to the dopant DP, which ultimately emits light. The red light emitting layer R may include a red host and a red dopant.

The red host may use Alq3, CBP, PVK, AND, TCTA, TPBI, TBADN, E3, DSA, or a mixture of two or more thereof, but the disclosure is not limited thereto.

Compounds including PtOEP, Ir(piq)₃, Btp₂Ir(acac), Ir(2-phq)₂(acac), Ir(2-phq)₃, Ir(flq)₂(acac), Ir(fliq)₂(acac), DCM, or DCJTB may be used as the red dopant, but the disclosure is not limited thereto.

The green light emitting layer G may include a green host and a green dopant.

The green host may use Alq3, CBP, PVK, AND, TCTA, TPBI, TBADN, E3, DSA, or a mixture of two or more thereof, but the disclosure is not limited thereto.

Ir(ppy)₃ tris(2-phenylpyridine) iridium, Ir(ppy)₂ (acac)(Bis(2-phenylpyridine)(Acetylacetonato)iridium(III), Ir(mppy)₃ (tris(2-(4-tolyl)phenylpiridine)iridium, C545T 10-(2benzothiazolyl)-1,1,7,7-tetramethyl-2,3,6,7-tetrahydro-1H,5H,11H-[1]benzopyrano [6,7,8-ij]-quinolizin11-one may be used as the green dopant, but the disclosure is not limited thereto.

The blue light emitting layer B may include a blue host and a blue dopant.

Alq₃, CBP(4,4′-N,N′-dicabazole-biphenyl), PVK(poly(n-vinylcabazole), ADN(9,10-di(naphthalene-2-yl)anthracene), TCTA, TPBI(1,3,5-tris(N-phenylbenzimidazole-2-yl)benzene), TBADN(3-tert-butyl-9,10-di(naphth-2-yl) anthracene), E3, DSA(distyrylarylene) or a mixture of two or more thereof may be used as the blue host, but the disclosure is not limited thereto.

Compounds including F₂Irpic, (F₂ppy)₂Ir(tmd), Ir(dfppz)₃, ter-fluorene, DPAVBi(4,4′-bis(4diphenylaminostyryl)biphenyl, TBPe or the like may be used as the blue dopant, but the disclosure is not limited thereto.

Meanwhile, the light emitting layer EML of the light emitting element provided in the normal area and the light emitting layer EML of the light emitting element provided in the optical area may include the same material, but the disclosure is not limited thereto. For example, the red light emitting layer R, the green light emitting layer G, and the blue light emitting layer B provided in the normal area and the optical area may each include the same material. As another example, the red light emitting layer R and the blue light emitting layer B provided in the normal area and the optical area may include the same material, and the green light emitting layer G may include a different material.

The light emitting element ED may include a hole transport layer HTL disposed between the first electrode AE and the light emitting layer EML. For example, the hole transport layer HTL may serve to transport holes. For example, the hole transport layer HTL may include a material including a tertiary amine or a tertiary amine including fluorine, but the disclosure is not limited thereto.

The light emitting element ED may include a hole injection layer HIL disposed on the first electrode AE, a hole transport layer HTL disposed on the hole injection layer, a light emitting layer EML disposed on the hole transport layer HTL, and an electron transport layer ETL disposed on the light emitting layer EML, but the disclosure is not limited thereto.

When a voltage is applied to the first electrode AE and the second electrode CE of the light emitting element ED, holes passing through the hole transport layer HTL and electrons passing through the electron transport layer ETL may be moved to the light emitting layer EML to form excitons, thereby emitting visible light from the light emitting layer EML.

The light emitting element ED may include an electron blocking layer EBL between the hole transport layer HTL and the light emitting layer EML.

The electron blocking layer EBL may include at least one of Tris(phenylpyrazole)iridium, BPAPF (9,9-bis[4-(N,N-bis-biphenyl-4-ylamino)phenyl]-9H-fluorene), Bis[4-(p,p-ditolylamino)phenyl]diphenylsilane, NPD(4,4′-bis[N-(1-napthyl)-N-phenyl-amino]biphenyl), mCP(N,N′-dicarbazolyl-3,5-benzene), MPMP(bis[4-(N,N-diethylamino)-2-methylphenyl](4-methylphenyl) methane) or a combination thereof, but the disclosure is not limited thereto.

Further, the electron blocking layer EBL may include an inorganic compound. For example, the electron blocking layer EBL may include at least one, or a combination, of halide compounds such as LiF, NaF, KF, RbF, CsF, FrF, MgF₂, CaF₂, SrF₂, BaF₂, LiCl, NaCl, KCl, RbCl, CsCl, or FrCI, and an oxide such as Li₂O, Li₂O₂, Na₂O, K₂O, Rb₂O, Rb₂O₂, Cs₂O, Cs₂O₂, LiAlO₂, LiBO₂, LiTaO₃, LiNbO₃, LiWO₄, Li₂CO, NaWO₄, KAlO₂, K2SiO₃, B₂O₅, Al₂O₃, or SiO₂, but the disclosure is not limited to them.

The electron blocking layer EBL serves as a buffer layer that blocks direct contact between the hole transport layer HTL and the light emitting layer EML, and may serve to prevent electrons from easily flowing into the hole transport layer HTL. In other words, the electron blocking layer EBL may enhance the efficiency and lifespan of the light emitting element ED by adjusting the injection and movement of electrons, and coupling of electrons with holes.

The electron transport layer ETL may be disposed on the light emitting layer EML. The electron transport layer ETL may adjust the movement speed of electrons so that electrons and holes meet in the light emitting layer EML to emit light. The electron transport layer ETL may include a material whose electron movement speed is several times larger than that of other materials. The electron transport layer ETL may include, e.g., at least one, or a combination, of Alq₃(tris(8-hydroxyquinolino)aluminum), PBD, TAZ, spiro-PBD, BAlq and SAlq, but the disclosure is not limited thereto.

The electron injection layer HIL may be disposed on the electron transport layer ETL. The electron injection layer HIL may transfer electrons introduced from the second electrode CE to the electron transport layer ETL.

The light emitting element ED may include a hole blocking layer HBL between the light emitting layer EML and the electron transport layer ETL. However, the disclosure is not limited thereto, and the light emitting element ED may not include the hole blocking layer HBL. The hole blocking layer HBL serves as a buffer layer that blocks direct contact between the electron transport layer ETL and the light emitting layer EML, and may serve to prevent holes from easily flowing into the electron transport layer ETL. The hole blocking layer HBL may enhance efficiency and lifespan of the light emitting element ED by controlling injection, movement, and coupling of holes with electrons.

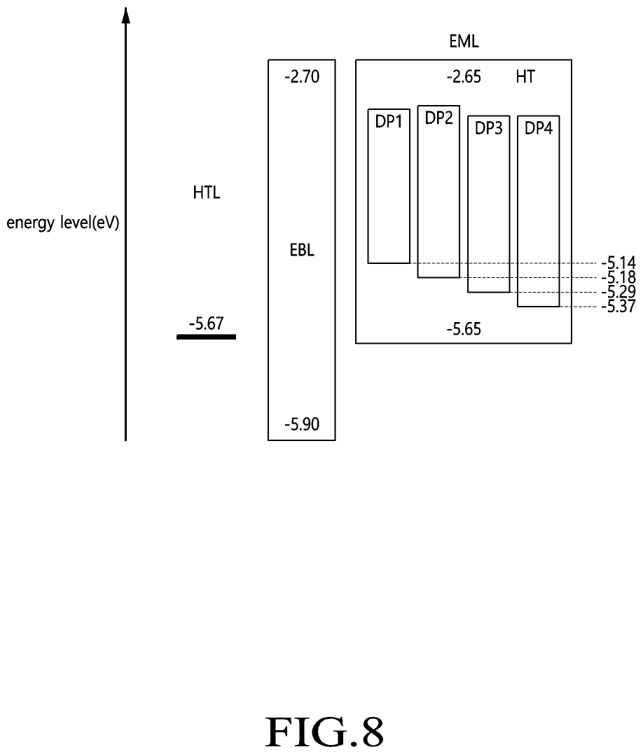

FIG. 8 is an example view illustrating an energy band diagram for a light emitting element disposed in an optical area of a display panel 110 according to embodiments of the disclosure. What is identical or similar to those described with reference to FIGS. 1 to 7 is omitted from the following description or briefly described below.

The energy band diagram illustrated in FIG. 8 is a view illustrating an energy band diagram between the hole transport layer HTL and the light emitting layer EML. In the energy band diagram, the energy band is depicted in a rectangular form, wherein the upper side of the rectangle denotes the lowest unoccupied molecular orbital (LUMO) energy level of each layer, and the lower side denotes the highest occupied molecular orbital (HOMO) energy level of each layer.

Referring to FIG. 8, an electron blocking layer EBL is disposed between the light emitting layer EML and the hole transport layer HTL, so that the light emitting layer EML and the hole transport layer HTL are disconnected from each other. In other words, the light emitting layer EML and the hole transport layer HTL are not in direct contact with each other.

When the light emitting element is turned on, holes injected from the first electrode AE move through the hole transport layer HTL and the electron blocking layer EBL to reach the light emitting layer EML, and electrons injected from the second electrode CE move through the electron transport layer ETL and the hole blocking layer HBL to reach the light emitting layer EML. When the light emitting element is turned off, the holes and electrons in the light emitting layer EML return to the first electrode AE and the second electrode CE, respectively. In this case, each layer may be formed of a material having appropriate bandgap energy so that holes and electrons may be easily injected and transferred to the light emitting layer EML.

For example, when the difference in the HOMO energy level between the hole transport layer HTL, the electron blocking layer EBL, and the light emitting layer EML is not significant, if the light emitting element is turned on, the holes may move quickly from the hole transport layer HTL to the light emitting layer EML and, even when it is turned off, the holes may move quickly from the light emitting layer EML to the hole transport layer HTL.

In this case, when the energy where the difference in HOMO energy level between the layers is at its maximum, that is, the HOMO threshold energy, is small, emission in the turn-off state may occur due to leakage current generated in the adjacent subpixel, causing holes to leak.

To prevent this phenomenon, as illustrated in FIG. 8, an electron blocking layer EBL having a relatively low HOMO energy level may be provided adjacent to the light emitting layer EML to increase the magnitude of the HOMO threshold energy.

In this structure, when the light emitting element ED changes from a turn-on state to a turn-off state, the holes accumulated in the light emitting layer EML are not released to the first electrode AE quickly, but instead are released slowly. As holes are released relatively slowly in the turn-off state of the light emitting element, residual light may remain on the surface of the display device.

Meanwhile, FIG. 8 illustrates the respective HOMO energy levels of the host HT and the dopants DP1 to DP4 included in the light emitting layer EML. The light emitting layer EML may include at least one dopant.

The host HT may include a p-type host pHT and an n-type host nHT. The p-type host pHT and the n-type host nHT may be included in a ratio of 4:6 to 7:3. When the p-type host pHT and the n-type host nHT are included in the above-described range, holes move relatively quickly to the first electrode AE in the light emitting layer EML during turn-off, thereby mitigating black transition.

The dopant DP may include a first dopant. The first dopant may be included in a ratio of 3 wt to 10 wt relative to the total weight of the light emitting layer EML. When the first dopant is included in the above-described range, holes may move relatively quickly to the first electrode AE in the light emitting layer EML during turn-off, thereby mitigating black transition.

Further, the dopant DP may further include a second dopant. The second dopant may be included in a ratio of 10 wt to 20 wt relative to the total weight of the light emitting layer. When the second dopant is included in the above-described range, holes may move relatively quickly to the first electrode AE in the light emitting layer EML during turn-off, thereby enhancing black transition.

Referring to FIG. 8, the HOMO energy level of the host HT may be lower than the HOMO energy level of the dopant DP. For example, the HOMO energy level of the host HT may be −5.37, and the HOMO energy level of the dopant DP may be −3.5 to −2.82.

Referring to FIG. 8, the HOMO energy level of the second dopant may be lower than the HOMO energy level of the first dopant. For example, the first dopant may be a dopant 1 DP1 and the second dopant may be a dopant 2 DP2. As another example, the first dopant may be a dopant 1 DP1, and the second dopant may be a dopant 3 DP3. As another example, the first dopant may be a dopant 1 DP1 and the second dopant may be a dopant 4 DP4.

A difference in HOMO energy between the host HT and the first dopant may be 0.46 or more, and a difference in HOMO energy between the host HT and the second dopant may be 0.3 or less. When the host, the first dopant, and the second dopant meet the HOMO energy difference in the above-described range, the holes may move relatively quickly from the first electrode AE to the light emitting layer EML to enhance the first frame response (FFR) during turn-on and, during turn-off, the holes may move relatively quickly from the light emitting layer EML to the first electrode AE to mitigate black transition.

Further, the light emitting layer EML provided in the normal area and the light emitting layer EML provided in the optical area may have different host and dopant combinations. For example, the light emitting layer EML provided in the normal area may include the host HT and the dopant 1 DP1, and the light emitting layer EML provided in the optical area may include the host HT and the dopant 3 DP3. As another example, the light emitting layer EML provided in the normal area may include the host HT and the dopant 1 DP1, and the light emitting layer EML provided in the optical area may include the host HT, the dopant 1 DP1, and the dopant 4 DP4, but the disclosure is not limited thereto.

Table 1 below is a table illustrating the black transition according to the ratio of the p-type host and the n-type host. On the other hand, in the table below, a lower the value of the black transition, and a higher the value of the FFR may mean that an enhancement has been achieved.

TABLE 1

| | | | | | Threshold | | | |
|---|---|---|---|---|---|---|---|---|
| | | | | | voltage | | Black | |
| Host | | Host | Host | Driving | (@1E- | | transition | |
| p:n rate | Dopant | HOMO | LUMO | voltage | 3 mA) | Efficiency | (ms) | |
| 4:6 | DP1 | −5.65 | −2.65 | 0.00 | 0.00 | 93% | 24 | ms |
| 6:4 | | | | +0.03 | −0.19 | 112% | 131 | ms |
| 7:3 | | | | +0.18 | −0.20 | 126% | 49 | ms |

Referring to Table 1, it may be identified that the black transition time and efficiency are enhanced by forming a light emitting layer by mixing the p-type host and the n-type host in their respective proportions.

Table 2 below shows the black transition according to the doping content of the dopant.

TABLE 2

| | | Thickness | | Threshold | | | |
|---|---|---|---|---|---|---|---|
| | | (Å) of light | | voltage | | Black | Black |
| | | emitting | Driving | (@1E- | | transition | transition |
| Dopant | Doping % | layer | voltage | 3 mA) | Efficiency | (ms) | (%) |
| DP1 | 4% | 325 | 0.00 | 0.00 | 100% | 50 | 100% |
| | 6% | 325 | +0.04 | −0.05 | 107% | 32 | 64% |
| | 8% | 325 | +0.12 | −0.07 | 114% | 30 | 60% |

Referring to Table 2, it may be identified that the efficiency and black transition are enhanced according to the doping content of the dopant.

Table 3 below shows the black transition and FFR according to the thickness of the light emitting layer.

TABLE 3

| | | Thickness | | |
|---|---|---|---|---|
| | | (Å) of | | |
| | | light | Black | FFR |
| | | emitting | transition | (@1.5 mA/ |
| Dopant | Doping % | layer | (%) | cm²) |
| DP1 | 0 | 325 | 100% | 80% |
| | 10% | 365 | 91% | 81% |
| | 20% | 405 | 83% | 79% |

Referring to Table 3, it may be identified that black transition and FFR are enhanced according to the thickness of the light emitting layer.

Table 4 below illustrates the black transition and FFR according to the type of dopant. The p-type host and n-type host are included in a ratio of 6:4, and the dopant is doped at 6%.

TABLE 4

| | | | | Black | FFR |
|---|---|---|---|---|---|
| | Host | Dopant | Dopant | transition | (@1.5 mA/ |
| Dopant | HOMO | HOMO | LUMO | (ms) | cm²) |
| DP 1 | −5.65 | −5.14 | −2.82 | 48 | 80% |
| DP 2 | | −5.18 | −2.79 | 22 | 58% |
| DP 3 | | −5.29 | −2.96 | 16 | 40% |
| DP 4 | | −5.37 | −3.05 | 9 | 82% |

Referring to Table 4, it may be identified that the black transition and FFR are enhanced in DP4 where the HOMO energy difference between the host and dopant is 0.30 or less.

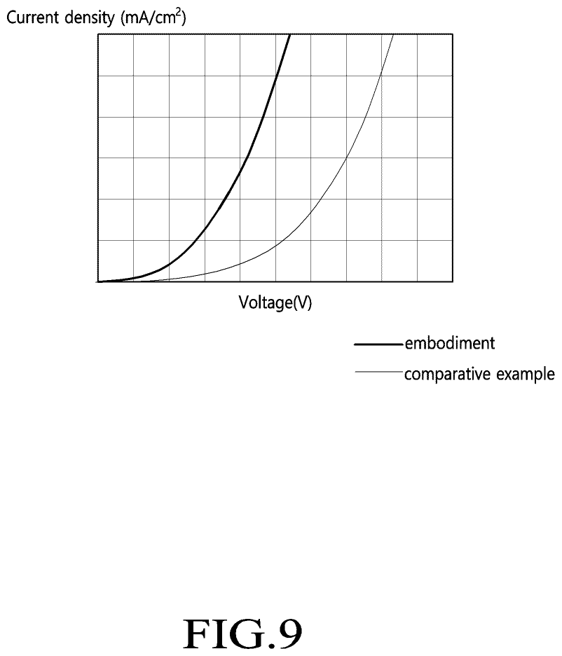

FIGS. 9 to 11 are example graphs illustrating characteristics of a light emitting element ED in an optical area OA of a display panel 110 according to embodiments of the disclosure. What is identical or similar to those described with reference to FIGS. 1 to 8 is omitted from the following description or briefly described below.

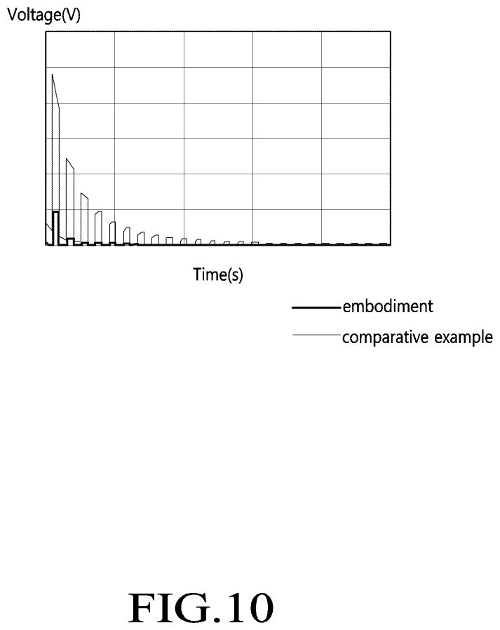

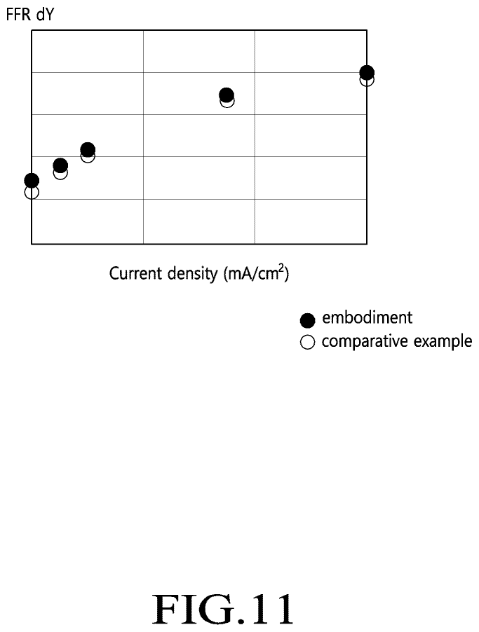

FIG. 9 is a graph illustrating the mobility of holes in an embodiment of the disclosure and a comparative example. FIG. 10 is a graph illustrating black transitions in the embodiment of the disclosure and the comparative example. FIG. 11 is a graph illustrating the first frame responses (FFR) in the embodiment of the disclosure and the comparative example. In the embodiment, dopant 4 is applied, and in the comparative example, dopant 1 is applied.

Referring to FIG. 9, it may be identified that the embodiment of the disclosure has a relatively fast mobility of holes compared to the comparative example. This may indicate that the mobility of the holes is high, resulting in the relatively fast formation and annihilation of excitons in the light emitting layer.

Referring to FIG. 10, it may be identified that the black transition is mitigated in the embodiment of the disclosure compared to the comparative example. As the black transition is mitigated, the luminance delay in the normal area and the optical area is reduced, leading to uniform surface characteristics.

Referring to FIG. 11, it may be identified that the FFR of the embodiment of the disclosure is enhanced compared to the comparative example. As the FFR is enhanced, the luminance delay in the optical area is reduced, resulting in uniform surface characteristics.

A display device according to an embodiment of the disclosure may be described as follows.

According to embodiments of the disclosure, there may be provided a display device comprising a plurality of light emitting elements disposed on a substrate, wherein at least one of the plurality of light emitting elements includes a first electrode disposed on the substrate, an electron blocking layer disposed on the first electrode, a light emitting layer disposed on the electron blocking layer and including a host and a dopant, and a second electrode disposed on the light emitting layer, and wherein a highest occupied molecular orbital HOMO energy level of the electron blocking layer is lower than an HOMO energy level of the host.

In the display device according to embodiments of the disclosure, the host may include a p-type host and an n-type host. The p-type host and the n-type host may be included in a ratio of 46 to 73.

In the display device according to embodiments of the disclosure, the dopant may include a first dopant. The first dopant may be included in a ratio of 3 wt to 10 wt relative to a weight of the light emitting layer.

In the display device according to embodiments of the disclosure, the dopant may further include a second dopant. The second dopant may be included in a ratio of 10 wt to 20 wt relative to the weight of the light emitting layer.

In the display device according to embodiments of the disclosure, a thickness of the light emitting layer may be 350 Å to 420 Å.

In the display device according to embodiments of the disclosure, an HOMO energy level of the host may be lower than an HOMO energy level of the dopant.

In the display device according to embodiments of the disclosure, an HOMO energy level of the second dopant may be lower than an HOMO energy level of the first dopant.

In the display device according to embodiments of the disclosure, a difference between the HOMO energy level of the host and the HOMO energy level of the first dopant may be 0.46 or more, and a difference between the HOMO energy level of the host and the HOMO energy level of the second dopant may be 0.3 Or less.

In the display device according to embodiments of the disclosure, the display device may further include a normal area having a first resolution and an optical area having a second resolution lower than the first resolution. The display device may comprise an optical electronic device positioned under the substrate while overlapping the optical area.

In the display device according to embodiments of the disclosure, at least one light emitting element may be disposed in the optical area.

In the display device according to embodiments of the disclosure, the plurality of light emitting elements may include light emitting elements respectively emitting red, green and blue light. The at least one light emitting element may be a light emitting element emitting the green light.

According to embodiments of the disclosure, there may be provided a display device having a light transmission structure in which an optical electronic device may normally receive light (e.g., visible light, infrared light, or ultraviolet light) without exposing the optical electronic device through the front surface of the display device.

According to embodiments of the disclosure, there may be provided a display device capable of implementing a full screen display by positioning various optical electronic devices to overlap under the display area of the display panel to allow the entire area of the display panel to be used as the display area.

According to embodiments of the disclosure, there may be provided a display device capable of quickly driving light emitting elements by adjusting the materials included in the light emitting layer in the normal area and the optical area.

According to embodiments of the disclosure, there may be provided a display device capable of quickly emitting holes by adjusting the materials included in the light emitting layer in the normal area and the optical area.

According to embodiments of the disclosure, there may be provided a display device capable of enhancing the surface characteristics of the display device by including different dopants in the light emitting layer in the optical area and the normal area.

According to embodiments of the disclosure, there may be provided a display device capable of increasing the reliability of the light emitting element by reducing the luminance deterioration and lifespan reduction in the display area.

According to embodiments of the disclosure, there may be provided a display device capable of increasing the efficiency and lifespan of the display device and reducing power consumption by decreasing the luminance deterioration and lifespan reduction in the display area.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed:

1. A display device, comprising:
a plurality of light emitting elements disposed on a substrate, wherein at least one of the plurality of light emitting elements includes:
a first electrode disposed on the substrate;
an electron blocking layer disposed on the first electrode;
a light emitting layer disposed on the electron blocking layer and including a host and a dopant; and
a second electrode disposed on the light emitting layer, and
wherein a highest occupied molecular orbital (HOMO) energy level of the electron blocking layer is lower than an HOMO energy level of the host.

2. The display device of claim 1, wherein the host includes a p-type host and an n-type host, and
wherein the p-type host and the n-type host are included in a ratio of 4:6 to 7:3.

3. The display device of claim 1, wherein the dopant includes a first dopant, and
wherein the first dopant is included in a ratio of 3 wt to 10 wt relative to a weight of the light emitting layer.

4. The display device of claim 3, wherein the dopant further includes a second dopant, and
wherein the second dopant is included in a ratio of 10 wt to 20 wt relative to the weight of the light emitting layer.

5. The display device of claim 4, wherein a thickness of the light emitting layer is 350 Å to 420 Å.

6. The display device of claim 4, wherein the HOMO energy level of the host is lower than an HOMO energy level of the dopant.

7. The display device of claim 6, wherein an HOMO energy level of the second dopant is lower than an HOMO energy level of the first dopant.

8. The display device of claim 7, wherein a difference between the HOMO energy level of the host and the HOMO energy level of the first dopant is 0.46 or more, and a difference between the HOMO energy level of the host and the HOMO energy level of the second dopant is 0.3 or less.

9. The display device of claim 1, further comprising: a normal area having a first resolution; and an optical area having a second resolution lower than the first resolution, wherein the display device comprises an optical electronic device positioned under the substrate while overlapping the optical area.

10. The display device of claim 9, wherein at least one light emitting element is disposed in the optical area.

11. The display device of claim 10, wherein the plurality of light emitting elements include light emitting elements configured to respectively emit red light, green light and blue light, and
wherein the at least one light emitting element is a light emitting element configured to emit the green light.
